(19) United States
(12) Patent Application Publication
(10) Pub. No.: US 2023/0292497 A1
(43) Pub. Date: Sep. 14, 2023

(54) MANUFACTURING METHOD OF SEMICONDUCTOR STRUCTURE

(71) Applicant: NANYA TECHNOLOGY CORPORATION, New Taipei City (TW)

(72) Inventor: Yao-Hsiung KUNG, Taoyuan City (TW)

(21) Appl. No.: 17/654,404

(22) Filed: Mar. 11, 2022

(51) Int. Cl. H01L 27/108

(52) U.S. Cl. CPC H01L 27/10888

(57) ABSTRACT

A manufacturing method of a semiconductor structure includes: forming a semiconductor layer between bit lines; patterning the semiconductor layer to form a plurality of cell contacts and trenches, wherein two of the cell contacts are separated by one of the trenches; and forming an isolation layer in the trenches. The semiconductor layer is formed between the bit lines such that no sacrificial layer is formed between the bit lines. A process of forming the sacrificial layer may be omitted.

### BACKGROUND

### Field of Invention

The present disclosure relates to a manufacturing method of a semiconductor structure.

### Description of Related Art

In general, a cell contact (CC) process usually is to fill a sacrificial layer between bit lines. Next, the sacrificial layer may be wet etched to form a first opening. An isolation layer may be formed in the first opening. Next, the sacrificial layer may be removed to form a second opening. A semiconductor layer may be formed in the second opening. Because the general process includes a step of forming the sacrificial layer, the cost may be increased. Furthermore, the semiconductor layer is formed in the second opening, so a smaller area is provided for forming the semiconductor layer such that it is possible to form voids while forming the semiconductor layer, which is disadvantageous to the semiconductor structure.

### SUMMARY

An aspect of the present disclosure is related to a manufacturing method of a semiconductor structure.

According to one embodiment of the present disclosure, a manufacturing method of a semiconductor structure includes: forming a semiconductor layer between bit lines; patterning the semiconductor layer to form a plurality of cell contacts and trenches, wherein two of the cell contacts are separated by one of the trenches; and forming an isolation layer in the trenches.

In one embodiment of the present disclosure, the method further includes: etching back the semiconductor layer; and polishing the semiconductor layer.

In one embodiment of the present disclosure, the isolation layer is formed after forming the cell contacts.

In one embodiment of the present disclosure, forming the isolation layer in the trenches includes: forming the isolation layer to cover the cell contacts and the bit lines, wherein the trenches are filled with the isolation layer; and etching back the isolation layer to expose the cell contacts.

In one embodiment of the present disclosure, etching back the isolation layer is performed such that the bit lines are free from coverage by the isolation layer.

In one embodiment of the present disclosure, the semiconductor layer is formed by chemical vapor deposition (CVD).

In one embodiment of the present disclosure, the semiconductor layer is made of a material that includes polysilicon.

In one embodiment of the present disclosure, the cell contacts are formed over an active area, and the active area is surrounded by a shallow trench isolation.

In one embodiment of the present disclosure, patterning the semiconductor layer is performed such that a width of the cell contacts is in a range from 20 nm to 40 nm.

In one embodiment of the present disclosure, a width of the isolation layer is in a range from 25 nm to 45 nm.

In one embodiment of the present disclosure, the method further includes forming a dielectric layer on sidewalls of the bit lines.

In one embodiment of the present disclosure, a width of the dielectric layer is in a range from 2 nm to 5 nm.

In one embodiment of the present disclosure, the dielectric layer is formed by atomic layer deposition (ALD), and the isolation layer is formed by chemical vapor deposition (CVD).

In one embodiment of the present disclosure, the isolation layer and the dielectric layer are made of a material that includes silicon nitride.

In one embodiment of the present disclosure, a top surface of the isolation layer is substantially coplanar with top surfaces of the bit lines, a top surface of the dielectric layer and top surfaces of the cell contacts.

In the aforementioned embodiments of the present disclosure, since the semiconductor layer is directly formed between the bit lines, a sacrificial layer is not necessary to be formed between the bit lines such that a process of forming the sacrificial layer may be omitted, which may save cost and time. Moreover, the semiconductor layer is formed prior to forming the isolation layer, so a larger area may be provided for forming the semiconductor layer such that no void may be formed while forming the semiconductor layer, which is advantageous to the semiconductor structure.

### BRIEF DESCRIPTION OF THE DRAWINGS

FIG. 1 illustrates a top view of a semiconductor structure according to one embodiment of the present disclosure.

FIG. 2 illustrates a cross-sectional view of the semiconductor structure of FIG. 1 along a line segment 2-2.

FIG. 3 illustrates a flow chart of a manufacturing method of a semiconductor structure according to one embodiment of the present disclosure.

FIGS. 4 to 9 illustrate top views at various steps of a manufacturing method of a semiconductor structure according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” “front,” “back” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

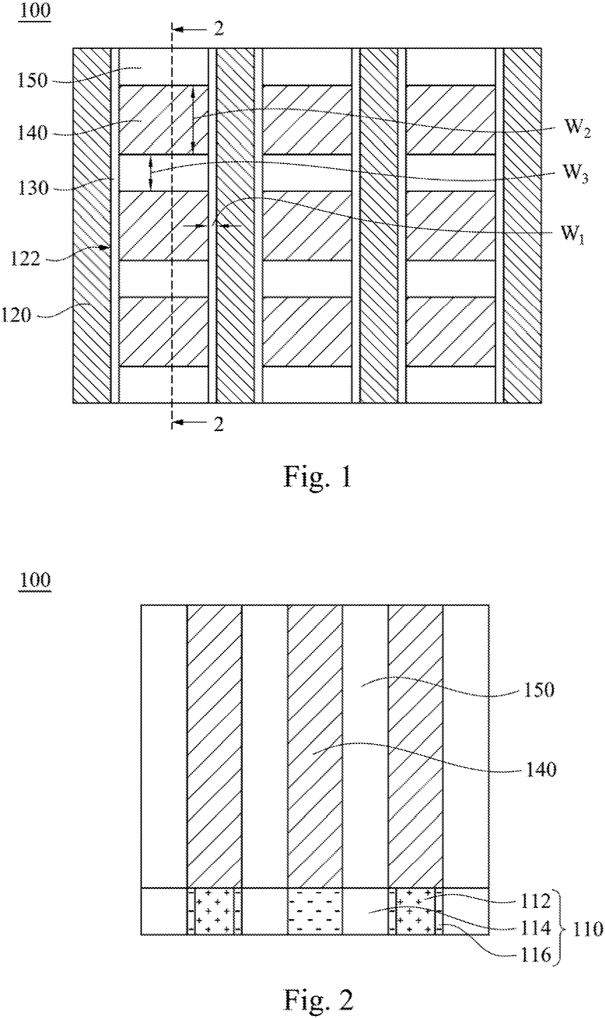

FIG. 1 illustrates a top view of a semiconductor structure 100 according to one embodiment of the present disclosure. FIG. 2 illustrates a cross-sectional view of the semiconductor structure 100 of FIG. 1 along a line segment 2-2. Referring to both FIG. 1 and FIG. 2, the semiconductor structure 100 includes a substrate 110, bit lines 120, a dielectric layer 130, a plurality of cell contacts 140 and an isolation layer 150. The substrate 110 includes an active area 112, a non-active area 114 and a shallow trench isolation 116. The active area 112 and the shallow trench isolation 116 of the substrate 110 are surrounded by the non-active area 114 of the substrate 110. The non-active area 114 of the substrate 110 may be made of a material that includes silicon nitride. The dielectric layer 130 is located on sidewalls 122 of the bit lines 120. For example, the dielectric layer 130 may be formed between the bit lines 120, and the dielectric layer 130 may be etched such that the dielectric layer 130 is located on the sidewalls 122 of the bit lines 120. In some embodiments, a width w1 of the dielectric layer 130 is in a range from 2 nm to 5 nm. The dielectric layer 130 may provide protection to the bit lines 120 such that the bit lines 120 may not be hurt while performing other processes. The dielectric layer 130 may be made of a material that includes silicon nitride.

In addition, the cell contacts 140 are located between the bit lines 120 (see FIG. 1) and over the active area 112, and the active area 112 is surrounded by the non-active area 114 and the shallow trench isolation 116 of the substrate 110 (see FIG. 2). A width w2 of the cell contacts 140 is in a range from 20 nm to 40 nm. The cell contacts 140 may provide a conductive effect to electrically connect with transistors (not shown). The isolation layer 150 is located between the cell contacts 140 (see FIG. 1), and the isolation layer 150 is located on the non-active area 114 of the substrate 110 (see FIG. 2). The isolation layer 150 may be made of a material that includes silicon nitride. A width w3 of the isolation layer 150 is in a range from 25 nm to 45 nm. The isolation layer 150 may provide an isolation effect to the cell contacts 140.

It is to be noted that the connection relationship of the aforementioned elements will not be repeated. In the following description, a manufacturing method of a semiconductor structure will be described.

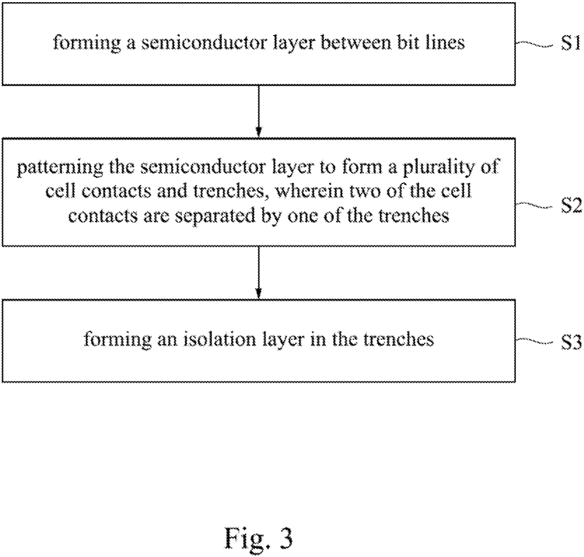

FIG. 3 illustrates a flow chart of a manufacturing method of a semiconductor structure according to one embodiment of the present disclosure. The manufacturing method of the semiconductor structure includes steps as outlined below. In step S1, a semiconductor layer is formed between bit lines. In step S2, the semiconductor layer is patterned to form a plurality of cell contacts and trenches, wherein two of the cell contacts are separated by one of the trenches. In step S3, an isolation layer is formed in the trenches. In the following description, the aforementioned steps will be described in detail.

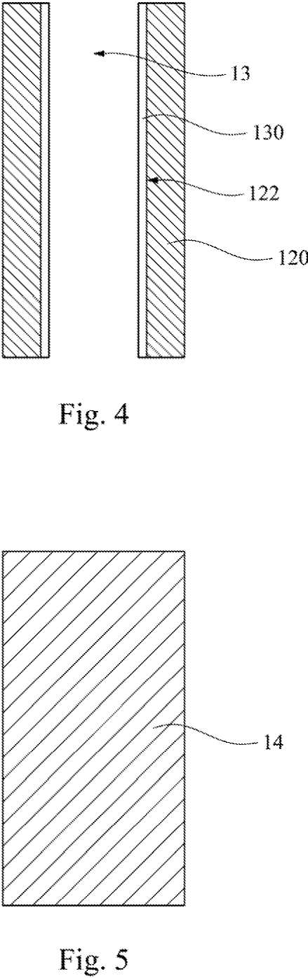

FIG. 4 to FIG. 9 illustrate top views at various steps of a manufacturing method of a semiconductor structure according to one embodiment of the present disclosure. Referring to FIG. 4, the method further includes forming the dielectric layer 130 on the sidewalls 122 of the bit lines 120. In some embodiments, the dielectric layer 130 may be made of a material that includes silicon nitride. The dielectric layer 130 may be formed by atomic layer deposition (ALD). For example, the dielectric layer 130 may be formed between the bit lines 120, and the dielectric layer 130 may be etched to open up an opening 13 such that the dielectric layer 130 is located on the sidewalls 122 of the bit lines 120 as shown in FIG. 4.

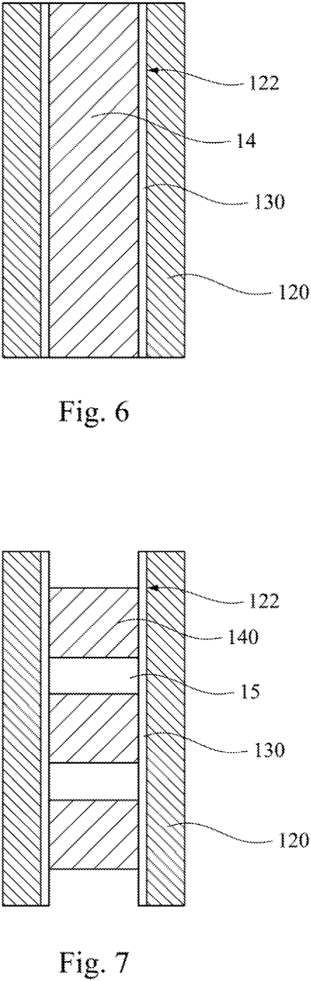

Referring to both FIG. 5 and FIG. 6, after the dielectric layer 130 is located on the sidewalls 122 of the bit lines 120, a semiconductor layer 14 is formed in the opening 13 (see FIG. 4) between the bit lines 120. The method further includes forming the semiconductor layer 14 to cover the bit lines 120 and the dielectric layer 130. In some embodiments, the semiconductor layer 14 may be formed by chemical vapor deposition (CVD). The semiconductor layer 14 may be made of a material that includes polysilicon. The method further includes etching back the semiconductor layer 14 and polishing the semiconductor layer 14. For example, polishing the semiconductor layer 14 may be performed by chemical-mechanical planarization (CMP). In addition, since the semiconductor layer 14 is formed between the bit lines 120, no sacrificial layer is formed between the bit lines 120. Therefore, a process of forming the sacrificial layer may be omitted, which may save cost and time.

Referring to FIG. 7, after the semiconductor layer 14 is etched back and polished, the semiconductor layer 14 is patterned by a mask to form a plurality of the cell contacts 140 and trenches 15, and two of the cell contacts 140 are separated by one of the trenches 15.

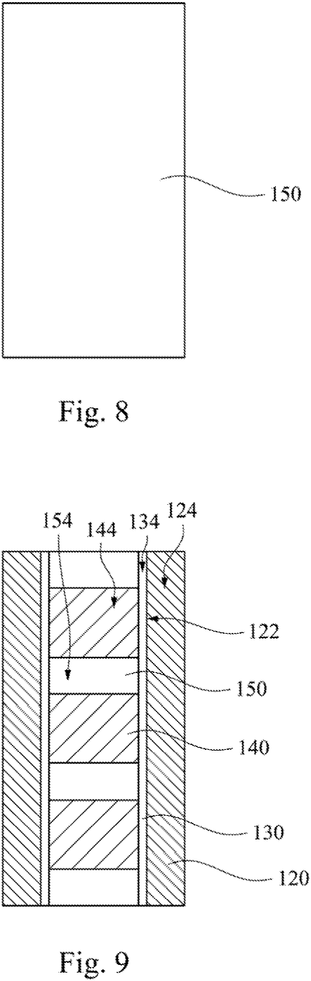

Referring to both FIG. 7 and FIG. 8, after the cell contacts 140 and the trenches 15 are formed, the isolation layer 150 is formed in the trenches 15. The method further includes forming the isolation layer 150 to cover the cell contacts 140 and the bit lines 120, and the trenches 15 are filled with the isolation layer 150. In some embodiments, the isolation layer 150 may be formed by chemical vapor deposition (CVD). The isolation layer 150 may be made of a material that includes silicon nitride.

Referring to FIG. 8 and FIG. 9, after forming the isolation layer 150 to cover the cell contacts 140 and the bit lines 120, the method further includes etching back the isolation layer 150 to expose the cell contacts 140. Etching back the isolation layer 150 is performed such that the bit lines 120 are free from coverage by the isolation layer 150. In addition, the isolation layer 150 is etched back such that a top surface 154 of the isolation layer 150 is substantially coplanar with top surfaces 124 of the bit lines 120, a top surface 134 of the dielectric layer 130 and top surfaces 144 of the cell contacts 140. Since the semiconductor layer 14 (see FIG. 6) is formed prior to forming the isolation layer 150, so a larger area may be provided for forming the semiconductor layer 14. In some embodiments, the isolation layer 150 is formed after forming the cell contacts 140 such that no void is formed in centers and four corners of the cell contacts 140.

In summary, since the semiconductor layer is directly formed between the bit lines, a sacrificial layer is not necessary to be formed between the bit lines such that a process of forming the sacrificial layer may be omitted, which may save cost and time. Moreover, the semiconductor layer is formed prior to forming the isolation layer, so a larger area may be provided for forming the semiconductor layer such that no void may be formed while forming the semiconductor layer, which is advantageous to the semiconductor structure.

Although the present disclosure has been described in considerable detail with reference to certain embodiments thereof, other embodiments are possible. Therefore, the spirit and scope of the appended claims should not be limited to the description of the embodiments contained herein. In view of the foregoing, it is intended that the present disclosure covers modifications and variations of this disclosure provided they fall within the scope of the following claims.

What is claimed is:

1. A manufacturing method of a semiconductor structure, comprising:
forming a semiconductor layer between bit lines;
patterning the semiconductor layer to form a plurality of cell contacts and trenches, wherein two of the cell contacts are separated by one of the trenches; and
forming an isolation layer in the trenches.

2. The manufacturing method of the semiconductor structure of claim 1, further comprising:
etching back the semiconductor layer; and
polishing the semiconductor layer.

3. The manufacturing method of the semiconductor structure of claim 1, wherein the isolation layer is formed after forming the cell contacts.

4. The manufacturing method of the semiconductor structure of claim 1, wherein forming the isolation layer in the trenches comprises:
forming the isolation layer to cover the cell contacts and the bit lines, wherein the trenches are filled with the isolation layer; and
etching back the isolation layer to expose the cell contacts.

5. The manufacturing method of the semiconductor structure of claim 4, wherein etching back the isolation layer is performed such that the bit lines are free from coverage by the isolation layer.

6. The manufacturing method of the semiconductor structure of claim 1, wherein the semiconductor layer is formed by chemical vapor deposition (CVD).

7. The manufacturing method of the semiconductor structure of claim 1, wherein the semiconductor layer is made of a material that comprises polysilicon.

8. The manufacturing method of the semiconductor structure of claim 1, wherein the cell contacts are formed over an active area, and the active area is surrounded by a shallow trench isolation.

9. The manufacturing method of the semiconductor structure of claim 1, wherein patterning the semiconductor layer is performed such that a width of the cell contacts is in a range from 20 nm to 40 nm.

10. The manufacturing method of the semiconductor structure of claim 1, wherein a width of the isolation layer is in a range from 25 nm to 45 nm.

11. The manufacturing method of the semiconductor structure of claim 1, further comprising:
forming a dielectric layer on sidewalls of the bit lines.

12. The manufacturing method of the semiconductor structure of claim 11, wherein a width of the dielectric layer is in a range from 2 nm to 5 nm.

13. The manufacturing method of the semiconductor structure of claim 11, wherein the dielectric layer is formed by atomic layer deposition (ALD), and the isolation layer is formed by chemical vapor deposition (CVD).

14. The manufacturing method of the semiconductor structure of claim 11, wherein the isolation layer and the dielectric layer are made of a material that comprises silicon nitride.

15. The manufacturing method of the semiconductor structure of claim 11, wherein a top surface of the isolation layer is substantially coplanar with top surfaces of the bit lines, a top surface of the dielectric layer and top surfaces of the cell contacts.
